(19) United States
(12) Patent Application Publication
(10) Pub. No.: US 2013/0207922 A1
(43) Pub. Date: Aug. 15, 2013

(54) PREVENTING OR REDUCING CORROSION TO CONDUCTIVE SENSOR TRACES

(71) Applicants: Simon Gillmore, Hampshire (GB); David Brent Guard, Hampshire (GB); Michael Thomas Morrione, San Jose, CA (US)

(72) Inventors: Simon Gillmore, Hampshire (GB); David Brent Guard, Hampshire (GB); Michael Thomas Morrione, San Jose, CA (US)

(21) Appl. No.: 13/369,538

(22) Filed: Feb. 9, 2012

(51) Int. Cl. G06F 3/044; H05K 3/00; H01R 43/00

(52) U.S. Cl. 345/174; 29/825; 29/846

(57) ABSTRACT

In one embodiment, a system includes a touch sensor comprising one or more electrodes and one or more connection pads electrically coupled to the one or more electrodes. The system also includes a protective coating formed over the one or more connection pads. The system further includes a circuit electrically coupled to one or more connection pads such that signals may be communicated from the one or more connection pads to the circuit.

### BACKGROUND

A touch sensor may detect the presence and location of a touch or the proximity of an object (such as a user's finger or a stylus) within a touch-sensitive area of the touch sensor overlaid on a display screen, for example. In a touch sensitive display application, the touch sensor may enable a user to interact directly with what is displayed on the screen, rather than indirectly with a mouse or touch pad. A touch sensor may be attached to or provided as part of a desktop computer, laptop computer, tablet computer, personal digital assistant (PDA), smartphone, satellite navigation device, portable media player, portable game console, kiosk computer, point-of-sale device, or other suitable device. A control panel on a household or other appliance may include a touch sensor.

There are a number of different types of touch sensors, such as (for example) resistive touch screens, surface acoustic wave touch screens, and capacitive touch screens. Herein, reference to a touch sensor may encompass a touch screen, and vice versa, where appropriate. When an object touches or comes within proximity of the surface of the capacitive touch screen, a change in capacitance may occur within the touch screen at the location of the touch or proximity. A touch-sensor controller may process the change in capacitance to determine its position on the touch screen.

In some aspects of touch-sensor technology, touch sensors that detect touch input include connection pads. Connection pads provide an interface to one or more component that process signals detected by touch sensors (e.g., dual-sided sensors), such as flexible printed circuits (FPC). Aspects of such components (such as a bond area of an FPC) have been placed between touch sensors and a touch lens/substrate itself and, as a result, have led to certain problems. One such problem is that moisture ingress may occur due to gaps being present between the screen and the touch sensor, potentially leading to oxidation and/or corrosion of such connection pads, which may adversely affect touch sensor functionality. Another problem that may arise is that sensor electrodes—(e.g., connection pads, fine lines of metal mesh, and tracking) may also react chemically with adhesives traditionally used to adhere various components of a sensor system, also potentially leading to oxidation and/or corrosion of such connection pads.

### BRIEF DESCRIPTION OF THE DRAWINGS

FIG. 1 illustrates one embodiment of a system used in a touch screen device including capacitively coupled connection pads;

FIGS. 2 and 3 illustrates one embodiment of manufacturing a touch sensing system; and

FIG. 4 illustrates an example touch-screen system.

### DESCRIPTION OF EXAMPLE EMBODIMENTS

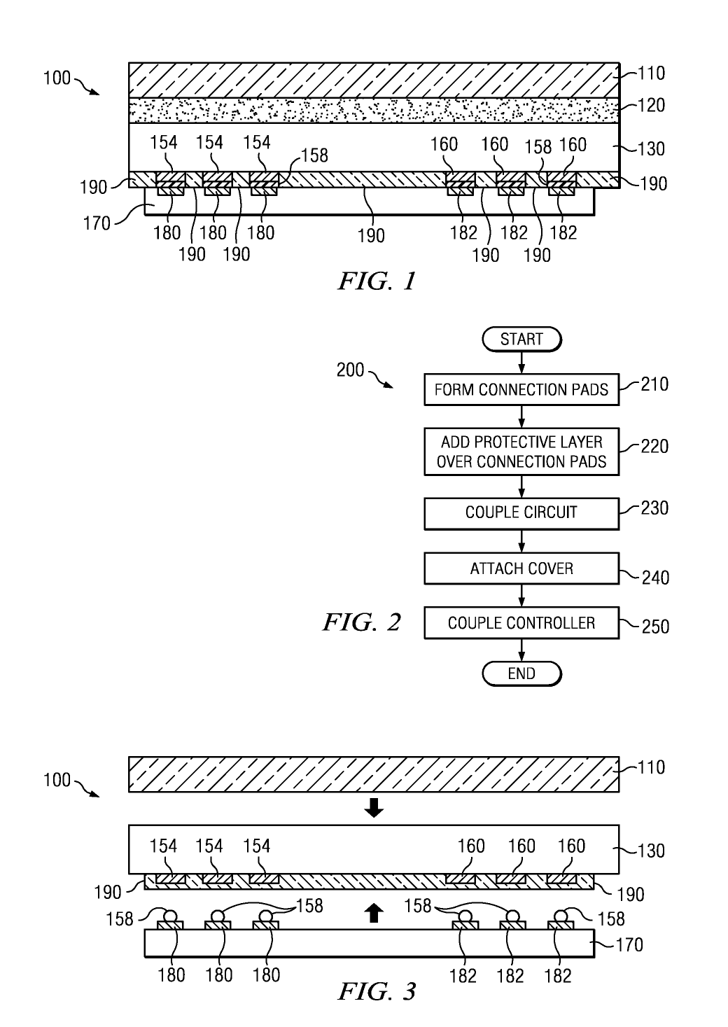

FIG. 1 illustrates one embodiment of system 100 used in a touch-screen device including capacitively coupled connection pads. System 100 includes touch sensor 130. Coupled to touch sensor 130 are connection pads 154 and 160. Cover 110 is coupled to touch sensor 130 via adhesive 120. Circuit 170 may be electrically coupled to connection pads 154 and 160 using connection pads 180 and 182, respectively. In some embodiments, touch sensor 130 may be configured to detect touches (e.g., capacitively, the touches performed by one or more fingers or a stylus) on cover 110 and produce signals indicative of the detection. Connection pads 160 may be electrically coupled to aspects of touch sensor 130 (such as electrodes) that are aligned in one axis (e.g., the x-axis) and connection pads 154 may be electrically coupled to aspects of touch sensor 130 (such as electrodes) that are aligned in a different axis (e.g., the y-axis). Connection pads 154 and 160 may provide signals to circuit 170.

In some embodiments, cover 110 may include material that allows for detection of touches on cover 110. For example, cover 110 may be made of a resilient material suitable for repeated touching such as, e.g., glass, polycarbonate, or poly(methyl methacrylate) (PMMA). Cover 110 may be clear, opaque, or may have one or more levels of suitable opacities. As an example only and not by way of limitation, cover 110 may have a thickness of approximately 1 mm. This disclosure contemplates any suitable cover made of any suitable material.

In some embodiments, adhesive 120 may be formed of Optically Clear Adhesives (OCA). Adhesives that have other levels of opacities other than optically clear may be used to implement adhesive 120. Adhesive 120 may be composed of suitable material (or combination of materials) that effectively attach touch sensor 130 to cover 110 and circuit 170. As an example only and not by way of limitation, adhesive 120 may have a thickness of approximately 0.05 mm.

In some embodiments, connection pads 180 and 182 of circuit 170 may be coupled to connection pads 154 and 160 using film 158. Film 158 may be electrically conductive and may facilitate the adhering of connection pads 180 and 182 to connection pads 154 and 160. As examples, film 158 may be implemented using Anisotropic Conduction Film (ACF) or anisotropic conduction paste (ACP).

In some embodiments, touch sensor 130 may include one or more electrodes that are configured to detect touches on the surface of cover 110. Touch sensor 130 may be a single-sided touch sensor or a double-sided touch sensor, such as a double-sided FLM (fine line metal) touch sensor. For example, touch sensor 130 may be configured such that electrodes aligned in one axis (e.g., the y-axis) may be present on one surface of touch sensor 130 and electrodes aligned in a different axis (e.g., the x-axis) may be present on another surface of touch sensor 130. As another example, touch sensor 130 may be configured such that electrodes aligned in one axis (e.g., the y-axis) may be present on the same surface of touch sensor 130 (e.g., the surface that faces cover 110) as electrodes aligned in a different axis (e.g., the x-axis).

One or more portions of the substrate of touch sensor 130 may be made of polyethylene terephthalate (PET) or another suitable material. This disclosure contemplates any suitable substrate with any suitable portions made of any suitable material. In particular embodiments, the drive or sense electrodes in touch sensor 130 may be made of indium tin oxide (ITO) in whole or in part. In particular embodiments, the drive or sense electrodes in touch sensor 130 may be made of fine lines of metal or other conductive material. As an example and not by way of limitation, one or more portions of the conductive material may be copper or copper-based and have a thickness of approximately 2 μm or less and a width of approximately 5 μm or less. As another example, one or more portions of the conductive material may be silver or silver-based and similarly have a thickness of approximately 5 μm or less and a width of approximately 10 μm or less. This disclosure contemplates any suitable electrodes made of any suitable material.

An electrode (whether a drive electrode or a sense electrode) may be an area of conductive material forming a shape, such as for example a disc, square, rectangle, other suitable shape, or suitable combination of these. One or more cuts in one or more layers of conductive material may (at least in part) create the shape of an electrode, and the area of the shape may (at least in part) be bounded by those cuts. In particular embodiments, the conductive material of an electrode may occupy approximately 100% of the area of its shape. As an example and not by way of limitation, an electrode may be made of indium tin oxide (ITO) and the ITO of the electrode may occupy approximately 100% of the area of its shape, where appropriate. In particular embodiments, the conductive material of an electrode may occupy substantially less than 100% of the area of its shape. As an example and not by way of limitation, an electrode may be made of fine lines of metal or other conductive material (such as for example copper, silver, or a copper- or silver-based material) and the fine lines of conductive material may occupy substantially less than 100% of the area of its shape in a hatched, mesh, or other suitable pattern. Although this disclosure describes or illustrates particular electrodes made of particular conductive material forming particular shapes with particular fills having particular patterns, this disclosure contemplates any suitable electrodes made of any suitable conductive material forming any suitable shapes with any suitable fills having any suitable patterns. Where appropriate, the shapes of the electrodes (or other elements) of a touch sensor may constitute in whole or in part one or more macro-features of the touch sensor. One or more characteristics of the implementation of those shapes (such as, for example, the conductive materials, fills, or patterns within the shapes) may constitute in whole or in part one or more micro-features of the touch sensor. One or more macro-features of a touch sensor may determine one or more characteristics of its functionality, and one or more micro-features of the touch sensor may determine one or more optical features of the touch sensor, such as transmittance, refraction, or reflection.

Touch sensor 130 may implement a capacitive form of touch sensing. In a mutual-capacitance implementation, touch sensor 130 may include an array of drive and sense electrodes forming an array of capacitive nodes. A drive electrode and a sense electrode may form a capacitive node. The drive and sense electrodes forming the capacitive node may come near each other, but not make electrical contact with each other. Instead, the drive and sense electrodes may be capacitively coupled to each other through the dielectric material separating them. A pulsed or alternating voltage applied to the drive electrode may induce a charge on the sense electrode, and the amount of charge induced may be susceptible to external influence (such as a touch or the proximity of an object). When an object touches or comes within proximity of the capacitive node, a change in capacitance may occur at the capacitive node and a controller (not depicted in FIG. 1) may measure the change in capacitance. By measuring changes in capacitance throughout the array, the controller may determine the position of the touch or proximity within the touch-sensitive area(s) of touch sensor 130.

In a self-capacitance implementation, touch sensor 130 may include an array of electrodes of a single type that may each form a capacitive node. When an object touches or comes within proximity of the capacitive node, a change in self-capacitance may occur at the capacitive node and a controller may measure the change in capacitance, for example, as a change in the amount of charge needed to raise the voltage at the capacitive node by a pre-determined amount. As with a mutual-capacitance implementation, by measuring changes in capacitance throughout the array, the controller may determine the position of the touch or proximity within the touch-sensitive area(s) of touch sensor 130. This disclosure contemplates any suitable form of capacitive touch sensing, where appropriate.

In particular embodiments, one or more drive electrodes may together form a drive line running horizontally or vertically or in any suitable orientation. Similarly, one or more sense electrodes may together form a sense line running horizontally or vertically or in any suitable orientation. In particular embodiments, drive lines may run substantially perpendicular to sense lines. Herein, reference to a drive line may encompass one or more drive electrodes making up the drive line, and vice versa, where appropriate. Similarly, reference to a sense line may encompass one or more sense electrodes making up the sense line, and vice versa, where appropriate.

Touch sensor 130 may have drive electrodes disposed in a pattern on one side of a substrate and sense electrodes disposed in a pattern on another side of the substrate or both the drive electrodes and the sense electrodes may be in patterns on the same side of touch sensor 130 (e.g., when touch sensor 130 is implemented as a single-sided touch sensor). An intersection of a drive electrode and a sense electrode may form a capacitive node. Such an intersection may be a location where the drive electrode and the sense electrode “cross” or come nearest each other in their respective planes. The drive and sense electrodes do not make electrical contact with each other—instead they are capacitively coupled to each other across a dielectric at the intersection. Although this disclosure describes particular configurations of particular electrodes forming particular nodes, this disclosure contemplates any suitable configuration of any suitable electrodes forming any suitable nodes.

In some embodiments, circuit 170 may be implemented using a flexible printed circuit. Any suitable set of materials and/or components may be used to implement circuit 170 that allows for the provision of signals to touch sensor 130 (via connection pads 154 and 160) and the reception of signals from touch sensor 130 (via connection pads 154 and 160). Circuit 170 may be coupled to other components, subsystems, or systems (not depicted in FIG. 1) that may determine signals to be transmitted to touch sensor 130 and/or that may determine how signals received from touch sensor 130 are processed.

As described above, a change in capacitance at a capacitive node of touch sensor 130 may indicate a touch or proximity input at the position of the capacitive node. A controller may detect and process the change in capacitance to determine the presence and location of the touch or proximity input. The controller may then communicate information about the touch or proximity input to one or more other components (such one or more central processing units (CPUs) or digital signal processors (DSPs)) of a device that includes touch sensor 130, which may respond to the touch or proximity input by initiating a function of the device (or an application running on the device) associated with it. Although this disclosure describes a particular controller having particular functionality with respect to a particular device and a particular touch touch sensor, this disclosure contemplates any suitable controller having any suitable functionality with respect to any suitable device and any suitable touch sensor.

In some embodiments, tracks of conductive material disposed on the substrate of touch sensor 130 may couple the drive or sense electrodes of touch sensor 130 to connection pads 154 and 160, also disposed on the substrate of touch sensor 130. Tracks may extend into or around (e.g. at the edges of) the touch-sensitive area(s) of touch sensor 130. Particular tracks may provide drive connections for coupling circuit 170 to drive electrodes of touch sensor 130, through which circuit 170 may supply drive signals to the drive electrodes. Other tracks may provide sense connections for coupling circuit 170 to sense electrodes of touch sensor 130, through which charge at the capacitive nodes of touch sensor 130 may be sensed. Tracks may be made of fine lines of metal or other conductive material. As an example and not by way of limitation, the conductive material of tracks may be copper or copper-based and have a width of approximately 100 μm or less. As another example, the conductive material of tracks may be silver or silver-based and have a width of approximately 10 to 100 μm. As a further example, the conductive material of tracks may be carbon nanotube based and have a width of approximately 100 μm or less. In particular embodiments, tracks may be made of ITO in whole or in part in addition or as an alternative to fine lines of metal or other conductive material. Although this disclosure describes particular tracks made of particular materials with particular widths, this disclosure contemplates any suitable tracks made of any suitable materials with any suitable widths. In addition to tracks, touch sensor 130 may include one or more ground lines terminating at a ground connector (which may be a connection pad) at an edge of the substrate of touch sensor 130 (similar to the tracks described above). In some embodiments, connection pads 154 and 160 may be implemented using conductive material, such as copper and may be located along one or more edges of the substrate, outside the touch-sensitive area(s) of touch sensor 130. Connection pads 154 and 160 may be implemented as tracks.

In some embodiments, system 100 may also include a protective layer 190 formed over connection pads 154 and 160 to protect connection pads 154 and 160 from moisture and/or corrosion, as described in greater detail elsewhere in this disclosure.

FIGS. 2 and 3 illustrate one embodiment of manufacturing a touch sensing system 100. In general, the steps illustrated in FIGS. 2 and 3 may be combined, modified, or deleted where appropriate, and additional steps may also be added to the example operation. Furthermore, the described steps may be performed in any suitable order. In some embodiments, the steps described below may be performed by any suitable combination of the elements discussed above with respect to FIG. 1.

The method may start at step 210, where, in some embodiments, connection pads 154 and 160 may be formed on a touch sensor 130. In some embodiments, connection pads 154 and 160 may be formed at the same time of mesh and or conductive tracking on touch sensor 130. The touch sensor 130 may include electrodes that are configured to detect touches on a cover (e.g., cover 110) that is near the touch sensor 130. Each connection pad 154 and 160 may be formed in FLM or printed in silver such that electrodes of the touch sensor may be coupled to one or more components that process signals received from the electrodes or provide signals to the electrodes. The touch sensor 130 may have electrodes on more than one side of the touch sensor 130 and connection pads 154 and 160 may be formed on more than one side of the touch sensor 130.

At step 220, in some embodiments, a protective layer 190 may be formed over connection pads 154 and 160. Protective layer 190 may comprise any suitable material configured to prevent ingress of moisture and/or corrosive chemicals to connection pads 154 and 160. In some embodiments, protective layer 190 may be substantially optically clear. In these and other embodiments, protective layer 190 may comprise PMMA, organic surface protection (OSP), acrylic, other polymer, and/or any other suitable material. In these or other embodiments, protective layer 190 may be comprised of a material selected to have optical properties (e.g., index of refraction) approximately equal to that of other components of system 100, such that optical uniformity of materials and other optical properties may be achieved. In some embodiments, in addition to being formed over connection pads 154 and 160, protective layer 190 may be formed over part or all of the region of the touch sensor 130 that contains the electrodes. Although FIG. 3 depicts protective layer 190 being formed over the substantially entire area of a side of touch sensor 130, in the region containing connection pads 154 and 160 (including over the areas of the touch sensor 130 between the connection pads), in certain other embodiments the protective layer may be formed on touch sensor 130 only local to the tracks and the connection pads 154 and 160. In these other embodiments, the protective layer may closely match the pattern of the tracks and the connection pads, with the protective layer being somewhat larger in extent than the tracks and the connection pads, so as to provide protection for both the “upper surfaces” of the tracks and connection pads (the surfaces facing away from the touch sensor substrate on which they are disposed) as well as their “side” surfaces.

At step 230, in some embodiments, a circuit 170 may be coupled to at least some of the connection pads 154 and 160 coupled at step 210. At this step, in some embodiments, the circuit 170 may only be arranged on one side of the touch sensor. For example, the circuit 170 may only be directly coupled to connection pads 154 and 160 that are located on one side of the touch sensor 130. The circuit 170 may be coupled using ACF bonding or ACP bonding. For example, in certain embodiments, film 158 may be implemented as ACF and ACP balls that, when heated and/or subject to pressure, deform to allow connection pads 154 and 160 to mate and electrically couple to connection pads 180 and 182. In such embodiments, protective layer 190 may be sufficiently thin so as to allow film 158 to penetrate protective layer 190 such that electrical connections may be made via conductive particles of film 158 between connection pads 154 and 160 of touch sensor 130 and connection pads 180 and 182 of circuit 170, while still protecting connection pads 154 and 160 from moisture and/or corrosion. In operation, film 158 may allow a galvanic flow of current between connection pads 154 and 160 and connection pads 180 and 182 of circuit 170. In addition to electrically coupling connection pads 154 and 160 to connection pads 180 and 182, film 158 may also be used to mechanically couple circuit 170 to touch sensor 130.

At step 240, in some embodiments, a cover 110 may be attached. Cover 110 may be attached using an adhesive 120 to the touch sensor 130.

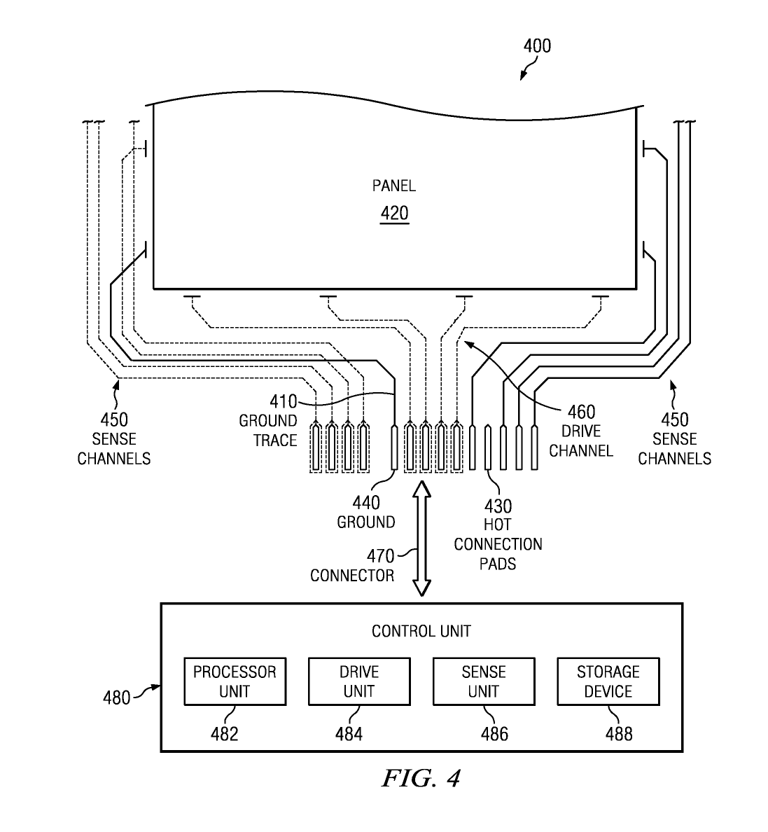

At step 250, in some embodiments, a controller may be coupled to the circuit attached at step 230, at which point the method may end. The controller may be configured to analyze signals generated by the touch sensor and/or may be configured to generate signals to be sent to the touch sensor. For example, the controller may send a drive signal to certain electrodes of the touch sensor and may analyze the signals received from electrodes that did not receive the drive signal to determine whether touch has occurred. Examples of the controller coupled at step 250 are discussed below with respect to control unit 480 of FIG. 4.

The steps recited above with respect to FIGS. 2 and 3 may be performed in any suitable order. For example, step 240 may occur before step 230 or step 220. As another example, step 250 may occur before step 240. Furthermore, although this disclosure describes and illustrates particular components, devices, or systems carrying out particular steps of the method of FIG. 2, this disclosure contemplates any suitable combination of any suitable components, devices, or systems carrying out any suitable steps of the method of FIG. 2.

Protective coating 190 may provide advantages over traditional approaches to manufacture of touch sensor systems. For example, under traditional approaches, an adhesive is applied to a touch sensor to encapsulate connection pads but an aperture must be formed to allow a circuit to be coupled to the connection pads. A conformal coating may then be applied after coupling of the circuit to prevent corrosion. However, connection pads may be exposed to moisture and corrosion in the time between formation of the apertures and addition of the conformal coating. However, addition of protective coating 190 during manufacture may provide increased coverage of connection pads during manufacture, thus potentially reducing moisture ingress and/or corrosion.

FIG. 4 illustrates an example touch-screen system 400. System 400 includes touch sensitive panel 420 that is coupled to connection pads 430 and ground 440 using ground trace 410, sense channels 450, drive channels 460. The drive and sense channels 450 and 460 are connected to a control unit 480 via a connector 470. In the example, the traces forming the channels have hot connection pads 430, to facilitate electrical connection via the connector 470. As an example, control unit 480 may cause a drive signal to be sent to panel 420 via drive channel 460. Signals detected in panel 420 may be sent to control unit 480 via sense channels 450. As discussed further below, control unit 480 may process the signals to determine whether an object has contacted panel 420 or is in proximity to panel 420. As depicted by the dotted lines in FIG. 4, sense channels 450 may be formed within a different layer of touch-screen system 400 than that of drive channel 460 and ground trace 410.

In particular embodiments, panel 420 may include a first layer of optically clear adhesive (OCA) beneath a cover panel. The cover panel may be clear and made of a resilient material suitable for repeated touching, such as for example glass, polycarbonate, or poly(methyl methacrylate) (PMMA). This disclosure contemplates any suitable cover panel made of any suitable material. The first layer of OCA may be disposed between the cover panel and the substrate with conductive material forming drive and sense electrodes. Panel 420 may also include a second layer of OCA and another substrate layer (which may be made of PET or another suitable material). The second layer of OCA may be disposed between the substrate with the conductive material making up the drive and sense electrodes and the other substrate layer, and the other substrate layer may be disposed between the second layer of OCA and an air gap to a display of a device including a touch sensor and a controller. As an example only and not by way of limitation, the cover panel may have a thickness of approximately 1 mm; the first layer of OCA may have a thickness of approximately 0.05 mm; the substrate with the conductive material forming the drive and sense electrodes may have a thickness of approximately 0.05 mm (including the conductive material forming the drive and sense electrodes); the second layer of OCA may have a thickness of approximately 0.05 mm; and the other layer of substrate disposed between the second layer of OCA and the air gap to the display may have a thickness of approximately 0.5 mm. Although this disclosure describes a particular number of particular layers made of particular materials and having particular thicknesses, this disclosure contemplates any suitable mechanical stack with any suitable number of any suitable layers made of any suitable materials and having any suitable thicknesses. In particular embodiments, panel 420 may be implemented using the embodiments disclosed above with respect to FIGS. 1-3.

In particular embodiments, control unit 480 may be one or more integrated circuits (ICs)—such as for example general-purpose microprocessors, microcontrollers, programmable logic devices or arrays, application-specific ICs (ASICs), tangible, non-transitory, computer-readable storage media—on a flexible printed circuit (FPC). Control unit 480 may include processor unit 482, drive unit 484, sense unit 486, and storage device 488. Drive unit 484 may supply drive signals to the drive electrodes of panel 420. Control unit 480 may supply drive signals to the drive electrodes of panel 420. Sense unit 486 may sense charge at the capacitive nodes included in panel 420 and provide measurement signals to processor unit 482 representing capacitances at the capacitive nodes. Processor unit 482 may control the supply of drive signals to the drive electrodes by drive unit 484 and process measurement signals from sense unit 486 to detect and process the presence and location of a touch or proximity input within the touch-sensitive area(s) of panel 420. Processor unit 482 may also track changes in the position of a touch or proximity input within the touch-sensitive area(s) of panel 420. Storage device 488 may store programming for execution by processor unit 482, including programming for controlling drive unit 484 to supply drive signals to the drive electrodes, programming for processing measurement signals from sense unit 486, and other suitable programming, where appropriate. Although this disclosure describes a particular control unit 480 having a particular implementation with particular components, this disclosure contemplates any suitable control unit having any suitable implementation with any suitable components.

Depending on the specific features implemented, particular embodiments may exhibit some, none, or all of the following technical advantages. Manufacturing of touch sensitive systems (e.g., touch screens) may be performed faster. Manufacturing of touch sensitive systems (e.g., touch screens) may be performed at a lower cost than conventional techniques. Increased yield may be realized during manufacturing. Tooling for manufacturing may become more simplified. Moisture ingress in touch sensitive systems (e.g., touch screens) may be reduced or eliminated. The reliability of an interface between a touch sensor and processing components may be enhanced. Other technical advantages will be readily apparent to one skilled in the art from the preceding figures and description as well as the proceeding claims. Particular embodiments may provide or include all the advantages disclosed, particular embodiments may provide or include only some of the advantages disclosed, and particular embodiments may provide none of the advantages disclosed.

Herein, reference to a computer-readable storage medium encompasses one or more non-transitory, tangible computer-readable storage media possessing structure. As an example and not by way of limitation, a computer-readable storage medium may include a semiconductor-based or other IC (such, as for example, a field-programmable gate array (FPGA) or an ASIC), a hard disk, an HDD, a hybrid hard drive (HHD), an optical disc, an optical disc drive (ODD), a magneto-optical disc, a magneto-optical drive, a floppy disk, a floppy disk drive (FDD), magnetic tape, a holographic storage medium, a solid-state drive (SSD), a RAM-drive, a SECURE DIGITAL card, a SECURE DIGITAL drive, or another suitable computer-readable storage medium or a combination of two or more of these, where appropriate. Herein, reference to a computer-readable storage medium excludes any medium that is not eligible for patent protection under 35 U.S.C. §101. Herein, reference to a computer-readable storage medium excludes transitory forms of signal transmission (such as a propagating electrical or electromagnetic signal per se) to the extent that they are not eligible for patent protection under 35 U.S.C. §101. A computer-readable non-transitory storage medium may be volatile, non-volatile, or a combination of volatile and non-volatile, where appropriate.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

This disclosure encompasses all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative.

What is claimed is:

1. A system comprising:
a touch sensor comprising one or more electrodes;
one or more connection pads electrically coupled to the one or more electrodes;
a protective coating formed over the one or more connection pads; and
a circuit electrically coupled to one or more connection pads such that signals may be communicated from the one or more connection pads to the circuit.

2. The system of claim 1, wherein the circuit is mechanically and electrically coupled to the touch sensor via a film.

3. The system of claim 2, the film comprising at least one of an anisotropic conduction film (ACF) and an anisotropic conduction paste (ACP)

4. The system of claim 2, wherein the protective coating is formed over at least part of a region of the touch sensor that contains the electrodes.

5. The system of claim 4, wherein the protective coating has one or more optical properties substantially similar to that of at least one of the touch sensor and an adhesive for mechanically bonding the circuit to the touch sensor.

6. The system of claim 4, wherein the protective coating has an index of refraction approximately equal to that of at least one of the touch sensor and an adhesive for mechanically bonding the circuit to the touch sensor.

7. The system of claim 1, wherein the protective coating is not formed over a region of the touch sensor that contains the electrodes.

8. The system of claim 1, wherein:
the circuit is mechanically and electrically coupled to the one or more connection pads via a film; and
the protective coating has a thickness such that, when the circuit is electrically coupled to the one or more connection pads, conductive particles of the film penetrate the protective coating, forming an electrical coupling between the one or more connection pads and the circuit.

9. The system of claim 8, wherein the electrical coupling between the circuit and the one or more connection pads is a physical contact allowing a galvanic flow of current between the one or more connection pads and the circuit.

10. The system of claim 1, the protective layer comprising at least one of poly(methyl methacrylate) (PMMA), organic surface protection (OSP), and acrylic.

11. The system of claim 1, the protective layer adapted to reduce ingress of moisture to the one or more connection pads.

12. The system of claim 1, the protective layer adapted to reduce ingress of one or more corrosive chemicals to the one or more connection pads.

13. A method comprising:
electrically coupling one or more connection pads to one or more electrodes, a touch sensor comprising the one or more electrodes;
forming a protective coating over the one or more connection pads; and
electrically coupling a circuit to the one or more connection pads such that signals may be communicated from the one or more connection pads to the circuit.

14. The method of claim 13, further comprising mechanically and electrically coupling the circuit to the touch sensor via an film.

15. The method of claim 14, the film comprising at least one of an anisotropic conduction film (ACF) and an anisotropic conduction paste (ACP)

16. The method of claim 14, wherein the protective coating has one or more optical properties substantially similar to that of at least one of the touch sensor and an adhesive for mechanically bonding the circuit to the touch sensor.

17. The method of claim 14, wherein the protective coating has an index of refraction approximately equal to that of at least one of the touch sensor and an adhesive for mechanically bonding the circuit to the touch sensor.

18. The method of claim 13, wherein:
electrically coupling a circuit to the one or more connection pads comprises mechanically and electrically coupling the circuit to the one or more connection pads via a film; and
the protective coating has a thickness such that, when the circuit is electrically coupled to the one or more connection pads, the conductive particles of the film penetrate the protective coating, forming an electrical coupling between the one or more connection pads and the circuit.

19. The method of claim 18, wherein the electrical coupling between the circuit and the one or more connection pads is a physical contact allowing a galvanic flow of current between the one or more connection pads and the circuit.

20. The method of claim 13, the protective layer comprising poly(methyl methacrylate) (PMMA), organic surface protection, and acrylic.

21. The system of claim 13, the protective layer adapted to preventingress of moisture to the one or more connection pads.

22. The system of claim 13, the protective layer adapted to preventingress of one or more corrosive chemicals to the one or more connection pads.
